(19) United States
(12) Patent Application Publication
(10) Pub. No.: US 2008/0254583 A1
(43) Pub. Date: Oct. 16, 2008

(54) Method of fabricating semiconductor device

(76) Inventors: Ken-ichi Takahashi, Ogaki-shi (JP); Yoshikazu Ibara, Motosu-gun (JP)

Correspondence Address: MCDERMOTT WILL & EMERY LLP, 600 13TH STREET, N.W., WASHINGTON, DC, 20005-3096, US

(21) Appl. No.: 12/078,313

(22) Filed: Mar. 28, 2008

(30) Foreign Application Priority Data
Mar. 30, 2007 (JP) JP2007-090047

(51) Int. Cl. H01L 21/8249

(52) U.S. Cl. 438/234; 257/E21.696

(57) ABSTRACT

A method of fabricating a semiconductor device includes steps of forming a gate electrode on the surface of a region of a semiconductor substrate provided with a first element, forming an insulating film to cover the surface of the gate electrode and another region of the semiconductor substrate provided with a second element and forming a sidewall insulating film covering the side surface of the gate electrode while leaving the insulating film on the region of the semiconductor substrate provided with the second element by a prescribed thickness by etching the insulating film up to an intermediate portion from the surface thereof.

### CROSS-REFERENCE TO RELATED APPLICATIONS

The priority application number JP2007-090047, method of fabricating semiconductor device, Mar. 30, 2007, Kenichi Takahashi, Yoshikazu Ibara, upon which this patent application is based is hereby incorporated by reference.

### BACKGROUND OF THE INVENTION

1. Field of the Invention

The present invention relates to a method of fabricating a semiconductor device, and more particularly, it relates to a method of fabricating a semiconductor device comprising a first element and a second element.

2. Description of the Background Art

A semiconductor device comprising a CMOS transistor (first element) and a bipolar transistor (second element) is known in general. The conventional semiconductor device has a region provided with the bipolar transistor and another region provided with the CMOS transistor on a substrate. In this semiconductor device, a TEOS oxide film is deposited on the overall surface of a silicon substrate after a gate oxide film and a polysilicon film for a gate electrode of the CMOS transistor are formed. Then, the overall surface of the TEOS oxide film is etched back, so that the TEOS oxide film is left only on the side surfaces of the polysilicon film for the gate electrode and the gate oxide film as sidewalls.

In a method of fabricating the conventional semiconductor device, however, the region of the silicon substrate provided with the bipolar transistor is disadvantageously damaged by etching when portions of the TEOS oxide film other than those left on the side surfaces of the polysilicon film for the gate electrode and the gate oxide film as the sidewalls are removed by etching.

### SUMMARY OF THE INVENTION

A method of fabricating a semiconductor device according to the present invention comprises steps of forming a gate electrode on the surface of a region of a semiconductor substrate provided with a first element, forming an insulating film to cover the surface of the gate electrode and another region of the semiconductor substrate provided with a second element and forming a sidewall insulating film covering the side surface of the gate electrode while leaving the insulating film on the region of the semiconductor substrate provided with the second element by a prescribed thickness by etching the insulating film up to an intermediate portion from the surface thereof.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a semiconductor device according to an embodiment of the present invention; and

FIGS. 1 to 15 are sectional views for illustrating a fabrication process for the semiconductor device according to the embodiment of the present invention.

### DESCRIPTION OF THE PREFERRED EMBODIMENTS

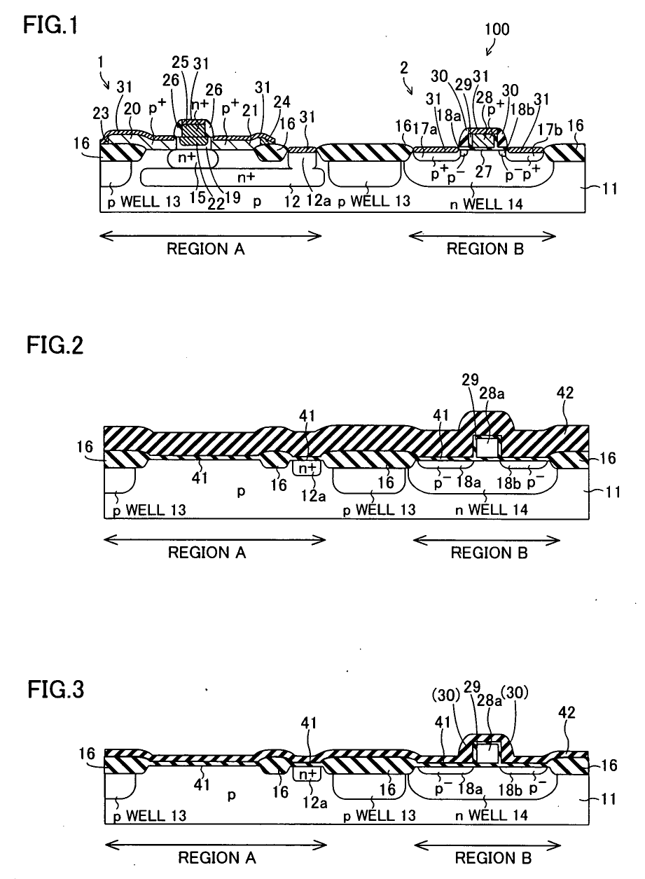

A semiconductor device 100 according to an embodiment of the present invention is constituted of a region A provided with a bipolar transistor 1 and another region B provided with a field-effect transistor 2, as shown in FIG. 1. The bipolar transistor 1 and the field-effect transistor 2 are examples of the “second element” and the “first element” in the present invention respectively. An n⁺-type subcollector region 12 including a reach-through region 12a, a p well 13 for element isolation and an n well 14 are formed on the surface of a p-type silicon substrate 11. An n⁺-type collector region 15 is formed on the surface of the subcollector region 12. An element isolation film 16 is formed on the surface of the p well 13 and the surfaces of the n well 14 and the silicon substrate 11. A p⁺-type high-concentration impurity region 17a and a p⁻-type low-concentration impurity region 18a as well as a p⁺-type high-concentration impurity region 17b and a p⁻-type low-concentration impurity region 18b functioning as source/drain regions of the field-effect transistor 2 are formed on the surface of the n well 14 at prescribed intervals, to hold a channel region therebetween.

A p-type inner base layer 19 and p⁺-type outer base layers 20 and 21 are formed on the surface of the collector region 15. An emitter layer 22 consisting of an n-type diffusion layer is formed on the surface of the inner base layer 19. Residues 23 and 24 of a polycrystalline silicon film 46 described later are formed on the side surfaces of the outer base layers 20 and 21 respectively. An n⁺-type emitter electrode 25 is formed on the surface of the emitter layer 22. A sidewall insulating film 26 is formed to cover the side surface of the emitter electrode 25.

A gate electrode 28 is formed on the surface of the silicon substrate 11 in the region B provided with the field-effect transistor 2 through a gate insulating film 27. An insulating film 29 is formed on the side surface of the gate electrode 28, to cover the gate electrode 28. A sidewall insulating film 30 is formed to cover the side surface of the insulating film 29.

A silicide film 31 is formed on the surfaces of the residues 23 and 24 of the polycrystalline silicon film 46, the outer base layers 20 and 21, the emitter electrode 25 and the reach-through region 12a of the bipolar transistor 1. The silicide film 31 is formed also on the surfaces of the impurity regions 17a and 17b and the gate electrode 28 of the field-effect transistor 2.

FIGS. 2 to 12 are sectional views for illustrating a fabrication process for the semiconductor device 100 according to the embodiment of the present invention respectively.

First, the element isolation film 16 is formed on the silicon substrate 11 by LOCOS (local oxidation of silicon), as shown in FIG. 2. Thereafter an oxide film 41 of SiO₂ is formed. The oxide film 41 is an example of the “second insulating film” in the present invention.

Then, resist films (not shown) are formed on prescribed regions of the surfaces of the oxide film 41 and the element isolation film 16, and phosphorus (P) is thereafter ion-implanted into a prescribed region of the region A, thereby forming the reach-through region 12a. Thereafter the resist films are removed.

Other resist films (not shown) are formed on other prescribed regions of the surfaces of the oxide film 41 and the element isolation film 16, and boron (B) ions are thereafter implanted, thereby forming the p well 13 for element isolation under the element isolation film 16. Thereafter the resist films are removed.

A polycrystalline silicon film is formed on the overall surfaces of the oxide film 41 and the element isolation film 16, and a resist film (not shown) is formed by photolithography and thereafter employed as a mask for etching the polycrystalline silicon film, thereby forming a polycrystalline silicon film 28a. Thereafter an insulating film 29 of SiO₂ is formed on the surface of the polycrystalline silicon film 28a by thermal oxidation.

Thereafter resist films (not shown) are formed on prescribed regions of the surfaces of the oxide film 41 and the element isolation film 16, and boron (B) ions are thereafter implanted, thereby forming the impurity regions 18a and 18b for serving as LDD (light doped drain) regions on surface portions of the n well 14 provided with no polycrystalline silicon film 28a. Thereafter the resist films are removed.

Then, a spacer insulating film 42 of SiO₂ having a thickness of about 200 nm is formed on the overall surfaces of the oxide film 41, the element isolation film 16 and the insulating film 29. The spacer insulating film 42 is an example of the “first insulating film” in the present invention.

Then, the surface of the spacer insulating film 42 is etched back, as shown in FIG. 3. According to this embodiment, the spacer insulating film 42 is not entirely etched back but left by a thickness of about 30 nm to about 70 nm. At this time, the spacer insulating film 42 may be left by a thickness sufficient for functioning as an implantation mask for the outer base layers 20 and 21. Thus, the spacer insulating film 42 remains on the surfaces of the region A provided with the bipolar transistor 1 and the region B provided with the field-effect transistor 2. The sidewall insulating film 30 is formed around the insulating film 29 covering the polycrystalline silicon film 28a of the field-effect transistor 2. Portions of the spacer insulating film 42 located on regions other than that provided with the sidewall insulating film 30 are removed in a step described later.

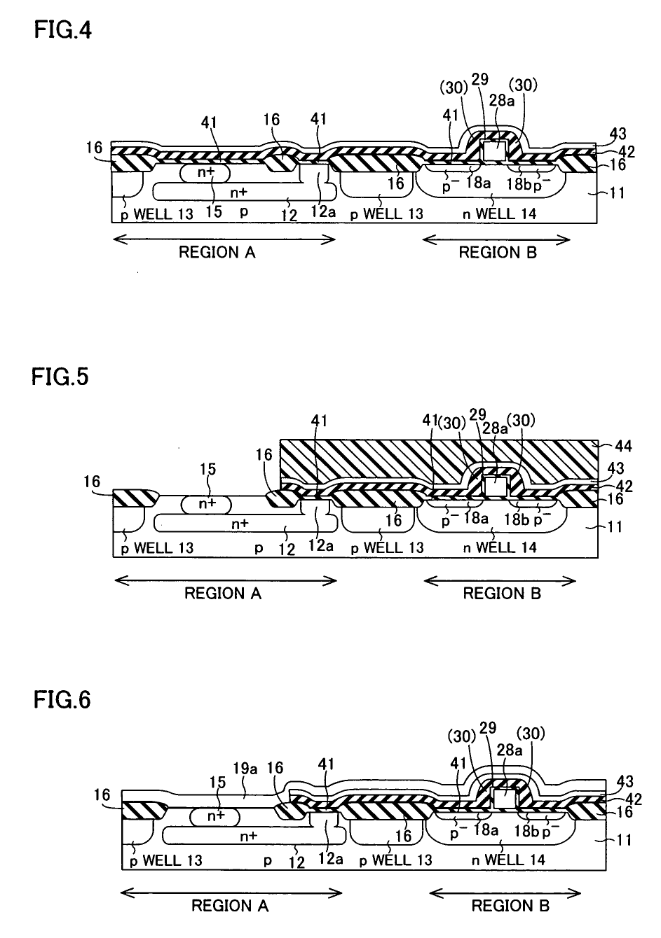

As shown in FIG. 4, a resist film (not shown) is formed on a prescribed region of the spacer insulating film 42, and phosphorus (P) is thereafter ion-implanted into a prescribed region of the region A provided with the bipolar transistor 1 and electrically activated, thereby forming the subcollector region 12. At this time, the reach-through region 12a and the subcollector region 12 are connected with each other. When phosphorus (P) is ion-implanted, the spacer insulating film 42 remaining on the region A provided with the bipolar transistor 1 functions as a protective film for preventing channeling and suppressing metal contamination in cleaning. Thereafter the resist film is removed.

Then, a resist film (not shown) is formed on a prescribed region of the spacer insulating film 42, and phosphorus (P) is thereafter ion-implanted into a prescribed region of the surface of the silicon substrate 11 provided with the subcollector region 12, thereby forming the collector region 15. Also at this time, the spacer insulating film 42 functions as a protective film for preventing the surface of the silicon substrate 11 from damage resulting from the ion implantation. Thereafter the resist film is removed. Then, a polycrystalline silicon film 43 is formed on the surface of the spacer insulating film 42.

As shown in FIG. 5, a resist film 44 is formed by photolithography, and the polycrystalline silicon film 43 is partially removed from the surface portion of the silicon substrate 11 provided with the bipolar transistor 1 by dry etching, and the spacer insulating film 42 is partially removed by wet etching. Further, the oxide film 41 is also partially removed. Thereafter the resist film 44 is removed. Consequently, the silicon substrate 11 is exposed on the prescribed region of the region B provided with the bipolar transistor 1, while the spacer insulating film 42 is left on the region B provided with the field-effect transistor 2.

As shown in FIG. 6, an epitaxial layer 19a is formed on the surfaces of the region A provided with the bipolar transistor 1 and the region B provided with the field-effect transistor 2 by epitaxially growing a silicon germanium (SiGe) layer doped with boron (B).

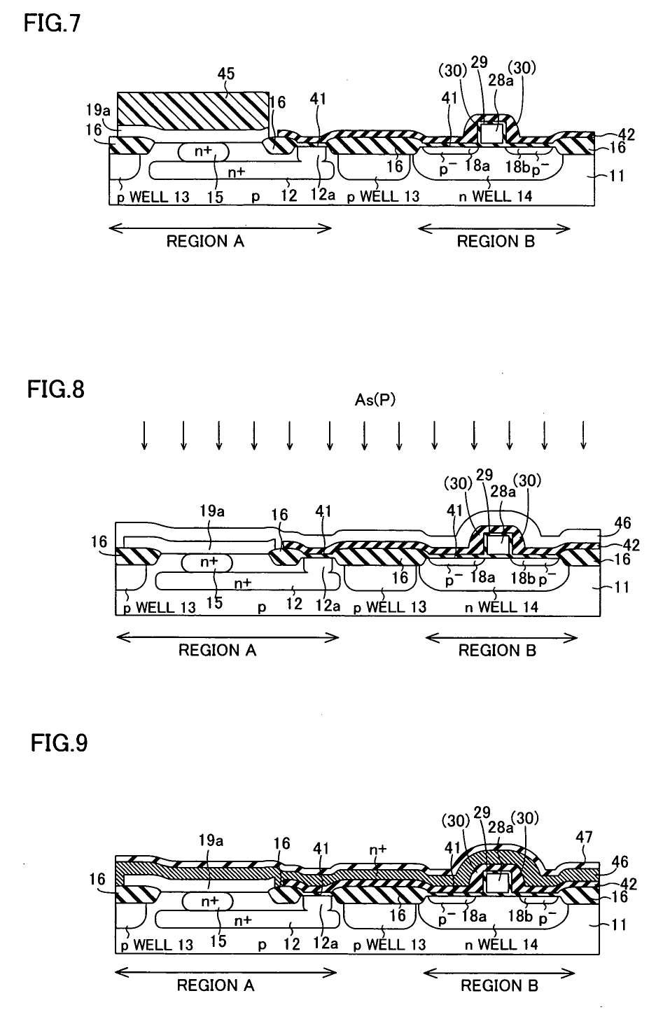

As shown in FIG. 7, a resist film 45 is formed by photolithography and thereafter employed as a mask for etching the epitaxial layer 19a thereby removing an unnecessary portion thereof.

As shown in FIG. 8, the polycrystalline silicon film 46 is formed on the surfaces of the element isolation film 16, the epitaxial layer 19a and the spacer insulating film 42 by low pressure CVD, and arsenic (As) or phosphorus (P) employed as an n-type impurity is thereafter ion-implanted. Thus, the polycrystalline silicon film 46 is converted to an n⁺-type polycrystalline silicon film 46.

As shown in FIG. 9, a silicon nitride film 47 is formed on the surface of the polycrystalline silicon film 46.

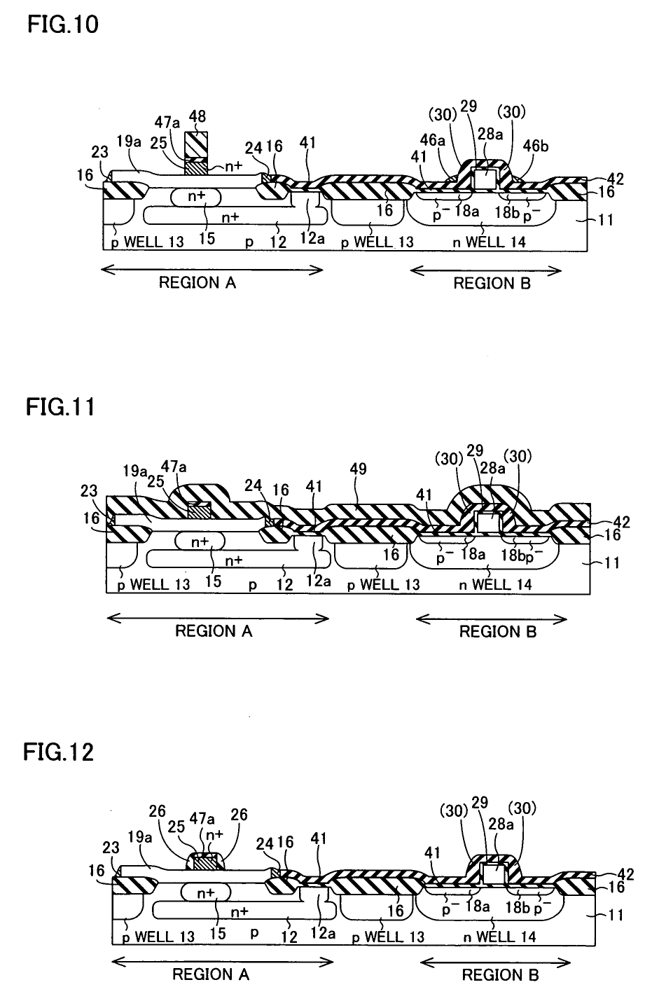

As shown in FIG. 10, a resist film 48 is formed on the surface of the silicon nitride film 47 by photolithography, and the silicon nitride film 47 and the polycrystalline silicon film 46 are thereafter partially removed by dry etching, thereby forming a silicon nitride film 47a and the emitter electrode 25. Then, the resist film 48 is removed, and residues 46a and 46b also formed on the surface of the spacer insulating film 42 in the region B provided with the field-effect transistor 2 are thereafter removed by etching. The residues 46a and 46b, formed on corners of the sidewall insulating film 30 of the field-effect transistor 2, can be easily removed by etching.

As shown in FIG. 11, a silicon oxide film 49 is formed on the surfaces of the residues 23 and 24 of the polycrystalline silicon film 46, the silicon nitride film 47a and the spacer insulating film 42 by low pressure CVD.

As shown in FIG. 12, the silicon oxide film 49 (see FIG. 11) is etched back by dry etching, thereby forming the sidewall insulating film 26 on the side surfaces of the emitter electrode 25 and the silicon nitride film 47a.

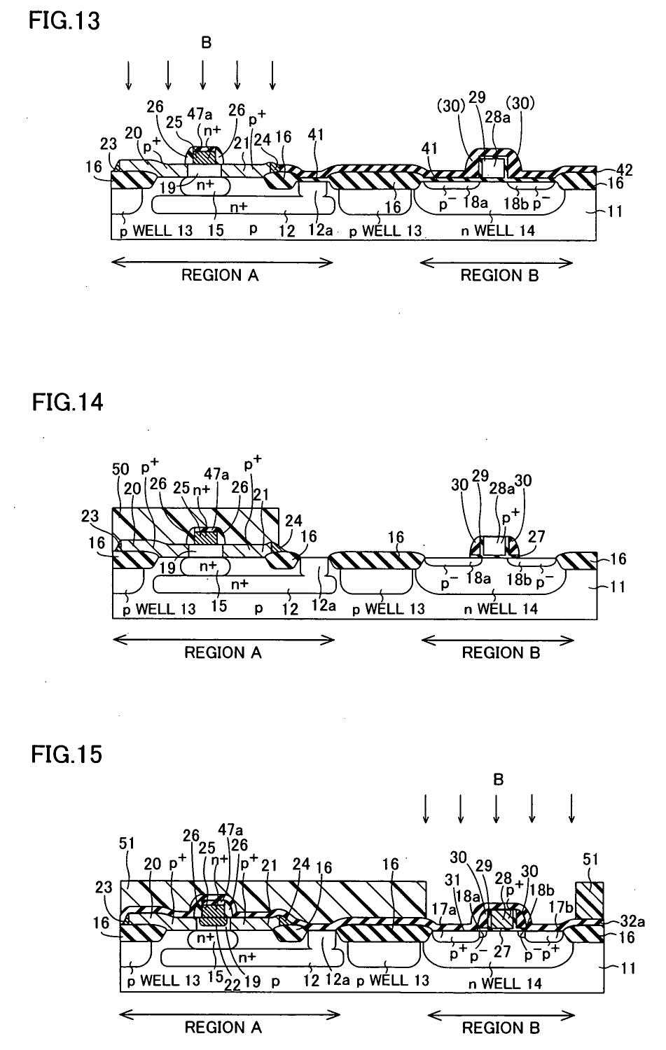

As shown in FIG. 13, the outer base layers 20 and 21 are formed on the epitaxial layer 19a by ion-implanting boron (B) and activating the ions by heat treatment. The remaining region of the epitaxial layer 19a provided with no outer base layers 20 and 21 forms the inner base layer 19.

As shown in FIG. 14, a resist film 50 is formed on the region A provided with the bipolar transistor 1, and prescribed regions of the oxide film 41 and the spacer insulating film 42 are thereafter removed by etching. Thus, the gate insulating film 27 is formed on the region B provided with the field-effect transistor 2, and the sidewall insulating film 30 is formed on the side surface of the insulating film 29 as the final shape of the spacer insulating film 42 at the same time. Thereafter the resist film 50 is removed.

As shown in FIG. 15, a silicon nitride film 32a is formed on the surfaces of the reach-through region 12a, the element isolation film 16, the impurity regions 17a and 17b, the outer base layers 20 and 21, the emitter electrode 25, the sidewall insulating film 26, the polycrystalline silicon film 28a (see FIG. 14), the insulating film 29 and the sidewall insulating film 30. Then, a resist film 51 is formed on a prescribed region of the surface of the silicon nitride film 32a, and boron (B) is thereafter ion-implanted, thereby forming the impurity regions 17a and 17b functioning as the source/drain regions of the field-effect transistor 2 along with the impurity regions 18a and 18b. Further, the gate electrode 28 of the field-effect transistor 2 is also formed. Thereafter the resist film 51 is removed.

Thereafter heat treatment is performed for diffusing the n-type impurity provided in the emitter electrode 25 into the inner base layer 19, thereby forming the emitter layer 22. Thus, an emitter-base junction is formed in the inner base layer 19.

Finally, the silicide film 31 of cobalt (Co) or titanium (Ti) is formed on the surfaces of the residues 23 and 24, the outer base layers 20 and 21, the emitter electrode 25, the reach-through region 12a, the impurity regions 17a and 17b and the gate electrode 28, thereby forming the semiconductor device 100.

According to this embodiment, as hereinabove described, the spacer insulating film 42 is left on the region A provided with the bipolar transistor 1 by the prescribed thickness in the step (see FIG. 3) of forming the side wall insulating film 30, whereby the region A provided with the bipolar transistor 1 can be prevented from damage resulting from etching dissimilarly to a case of entirely removing the spacer insulating film 42 from the region A provided with the bipolar transistor 1 by etching.

According to this embodiment, as hereinabove described, the method of fabricating the semiconductor device 100 comprises the step (see FIG. 4) of forming the subcollector region 12 and the collector region 15 by ion-implanting phosphorus (P) into the region A of the silicon substrate 11 provided with the bipolar transistor 1 through the spacer insulating film 42, left on the region A of the silicon substrate 11 provided with the bipolar transistor 1, employed as a protective film, whereby the region A of the silicon substrate 11 provided with the bipolar transistor 1 can be easily prevented from damage upon ion implantation of phosphorus (P) through the spacer insulating film 42 left on the region A of the silicon substrate 11 provided with the bipolar transistor 1. Further, no protective film may be newly formed on the region A provided with the bipolar transistor 1 for the step of ion-implanting the impurity dissimilarly to the case of entirely removing the spacer insulating film 42 from the region A provided with the bipolar transistor 1 by etching, whereby the fabrication process can be simplified.

According to this embodiment, as hereinabove described, the step of forming the sidewall insulating film 30 includes the step (see FIG. 3) of forming the sidewall insulating film 30 while leaving the spacer insulating film 42 formed on the surfaces of the impurity regions 17a and 17b formed on the region B provided with the field-effect transistor 2 for serving as the source/drain regions by the prescribed thickness, whereby the impurity regions 17a and 17b can be prevented from damage resulting from etching dissimilarly to a case of entirely removing the spacer insulating film 42 from the surfaces of the impurity regions 17a and 17b formed on the region B provided with the field-effect transistor 2.

According to this embodiment, as hereinabove described, the method of fabricating the semiconductor device 100 comprises the step (see FIG. 5) of partially removing the spacer insulating film 42 from the region A of the silicon substrate 11 provided with the bipolar transistor 1 while leaving the spacer insulating film 42 on the region B of the silicon substrate 11 provided with the field-effect transistor 2 by the prescribed thickness. Thus, the spacer insulating film 42 is left on the region B of the silicon substrate 11 provided with the field-effect transistor 2 by the prescribed thickness, whereby the region B provided with the field-effect transistor 2 can be prevented from channeling and metal contamination in a cleaning step or the like.

Although the present invention has been described and illustrated in detail, it is clearly understood that the same is by way of illustration and example only and is not to be taken by way of limitation, the spirit and scope of the present invention being limited only by the terms of the appended claims.

For example, while the npn bipolar transistor is formed in the aforementioned embodiment, the present invention is not restricted to this but a pnp bipolar transistor may alternatively be formed.

While the p-type field-effect transistor is formed in the aforementioned embodiment, the present invention is not restricted to this but an n-type field-effect transistor may alternatively be formed.

What is claimed is:

1. A method of fabricating a semiconductor device, comprising steps of:
forming a gate electrode on the surface of a region of a semiconductor substrate provided with a first element;
forming a first insulating film to cover the surface of said gate electrode and another region of said semiconductor substrate provided with a second element; and
forming a sidewall insulating film covering the side surface of said gate electrode while leaving said first insulating film on said region of said semiconductor substrate provided with said second element by a prescribed thickness by etching said first insulating film up to an intermediate portion from the surface thereof.

2. The method of fabricating a semiconductor device according to claim 1, wherein
said first element is a field-effect transistor, and said second element is a bipolar transistor.

3. The method of fabricating a semiconductor device according to claim 2, further comprising a step of forming a collector region by ion-implanting an impurity into said region of said semiconductor substrate provided with said bipolar transistor through said first insulating film, remaining on said region of said semiconductor substrate provided with said bipolar transistor, employed as a protective film.

4. The method of fabricating a semiconductor device according to claim 3, wherein
said step of forming said collector region includes steps of forming a subcollector region through said first insulating film employed as a protective film and forming said collector region above said subcollector region through said first insulating film employed as a protective film.

5. The method of fabricating a semiconductor device according to claim 2, wherein
said step of forming said sidewall insulating film includes a step of forming said sidewall insulating film while leaving said first insulating film formed on the surface of a source/drain region of said region of said semiconductor substrate provided with said field-effect transistor by a prescribed thickness.

6. The method of fabricating a semiconductor device according to claim 2, further comprising a step of removing said first insulating film from said region of said semiconductor substrate provided with said bipolar transistor while leaving said first insulating film on said region of said semiconductor substrate provided with said field-effect transistor by said prescribed thickness.

7. The method of fabricating a semiconductor device according to claim 6, further comprising a step of forming a first semiconductor layer serving as a base layer to cover said first insulating film left on said region of said semiconductor substrate provided with said field-effect transistor and to be in contact with the surface of said region of said semiconductor substrate provided with said bipolar transistor, from which said first insulating film is removed.

8. The method of fabricating a semiconductor device according to claim 7, further comprising a step of forming a portion serving as said base layer by etching said first semiconductor layer while leaving said first insulating film on said region of said semiconductor substrate provided with said field-effect transistor.

9. The method of fabricating a semiconductor device according to claim 8, further comprising a step of forming a second semiconductor layer serving as an emitter electrode to cover said first insulating film left on said region of said semiconductor substrate provided with said field-effect transistor and to be in contact with the surface of said portion for serving as said base layer.

10. The method of fabricating a semiconductor device according to claim 9, further comprising a step of forming said emitter electrode on said portion for serving as said base layer by etching said second semiconductor layer while leaving said first insulating film on said region of said semiconductor substrate provided with said field-effect transistor.

11. The method of fabricating a semiconductor device according to claim 10, further comprising a step of forming an outer base layer by implanting an impurity into a prescribed region of said portion for serving as said base layer through said emitter electrode employed as a mask while leaving said first insulating film on said region of said semiconductor substrate provided with said field-effect transistor.

12. The method of fabricating a semiconductor device according to claim 11, further comprising a step of removing a portion of said first insulating film, left on said region of said semiconductor substrate provided with said field-effect transistor, formed on the surface of said source/drain region after formation of said emitter electrode and said outer base layer.

13. The method of fabricating a semiconductor device according to claim 2, further comprising a step of forming a second insulating film serving as a gate insulating film of said field-effect transistor on the surface of said region of said semiconductor substrate provided with said field-effect transistor and the surface of said region of said semiconductor substrate provided with said bipolar transistor in advance of said step of forming said first insulating film.

14. The method of fabricating a semiconductor device according to claim 13, further comprising a step of forming a reach-through region by implanting an impurity into the surface of said region of said semiconductor substrate provided with said bipolar transistor while leaving said second insulating film serving as said gate insulating film on the surface of said region of said semiconductor substrate provided with said field-effect transistor and the surface of said region of said semiconductor substrate provided with said bipolar transistor.

15. The method of fabricating a semiconductor device according to claim 13, further comprising a step of simultaneously forming the final shape of said sidewall insulating film covering the side surface of said gate electrode and said gate insulating film by removing a portion of said first insulating film, left on said region of said semiconductor substrate provided with said field-effect transistor, formed on the surface of said source/drain region and a portion of said second insulating film, for serving as said gate insulating film, formed on the surface of said source/drain region by etching.
